(19) United States
(12) Patent Application Publication
(10) Pub. No.: US 2026/0312487 A1
(43) Pub. Date: Oct. 8, 2026

(54) METHOD OF DISCHARGING A HIGH-POWER COMPONENT, POWER ELECTRONICS ARRANGEMENT ACCORDING TO THIS METHOD, AND MOTOR VEHICLE WITH A POWER ELECTRONICS ARRANGEMENT

(71) Applicant: AUDI AG, Ingolstadt (DE)

(72) Inventor: Daniel RUPPERT, Lenting (DE)

(21) Appl. No.: 19/461,565

(22) Filed: Jan. 27, 2026

(30) Foreign Application Priority Data
Jan. 29, 2025 (DE) 102025103098.7

(51) Int. Cl. H02M 1/32; H02M 7/797; H05K 7/20

(52) U.S. Cl. CPC H02M 1/322; H02M 7/797; H05K 7/2089

(57) ABSTRACT

A method of discharging a high-power component of a motor vehicle, wherein the high-power component includes a plurality of transistors connected to form a multiphase T-type converter circuit. The method includes: generating, by a gate driver, control voltages for the transistors, wherein an electrical current flow of a drain-source channel of each of the transistors is controlled by the control voltages, wherein, for discharging the high-power component, each of the transistors of the multiphase T-type converter circuit is brought into a discharge state by way of the control voltages, wherein the drain-source channel of each of the transistors realizes a resistance, and wherein the discharging of the high-power component takes place by way of the resistance realized by the drain-source channel of each of the plurality of transistors.

### BACKGROUND

### Technical Field

The present disclosure relates to a method for discharging a high-power component of a motor vehicle.

### Description of the Related Art

Hybrid or electric vehicles comprise high-power components that are connected to a high-voltage on-board electrical system. The high-power components can be traction converters or high-voltage DC/DC converters. It is also conceivable that the high-power component is a component of an on-board charger or an electric air conditioning compressor or an electric heater.

For reasons of safety in use and functional safety, a circuit for active discharge is typically provided in high-voltage components. This discharge circuit usually consists of a semiconductor switching element, such as a MOSFET, and an ohmic load or an electrical resistor, wherein the energy is converted into heat or dissipated during discharge by way of the ohmic load.

Another approach in connection with discharging a high-voltage component by way of energy conversion provides for using existing semiconductor components of the high-voltage component, such as transistors, for this purpose. Corresponding concepts are known, for example, from CN 2 20 775 673 U or DE 10 2022 109 285 A1.

### BRIEF SUMMARY

Embodiments of the present disclosure provide an improved concept in connection with the discharge of a high-voltage component of a motor vehicle, in particular with regard to a simple and cost-effective implementation as well as an effective mode of operation.

According to the disclosure, a method of for discharging a high-power component of a motor vehicle is provided wherein the high-power component comprises a plurality of transistors connected to form a multiphase, in particular three-phase, T-type converter circuit, wherein a gate driver generates control voltages for the transistors, by way of which an electrical current flow of a drain-source channel of the respective transistor is controlled in each case, wherein, for discharging the high-power component, the transistors of the converter circuit are brought into a discharge state by way of the control voltages, in which the drain-source channel of the respective transistor realizes a resistor, wherein the discharging of the high-power component takes place by way of these resistors.

The disclosure is based in part on the idea of realizing a concept in which it is possible to implement the functionality of discharging the high-power component not by way of additional components, but instead exclusively by using components of the high-performance component that are already present for its discharge. This means that additional components such as a resistor specifically provided for this purpose can be dispensed with, which is advantageous in terms of the components required and therefore in terms of costs and weight. These components, which are already present, are the gate driver, by way of which control voltages or signals are generated for controlling the transistors in normal or converter mode, and the transistors, whose original purpose is to realize the rectification or conversion of electrical voltage carried out by way of the converter circuit.

A further idea of the disclosure is based on the fact that the converter circuit is realized as a multiphase, preferably as a three-phase, T-type converter circuit. This circuit incorporates a plurality of transistors, in particular at least twelve, preferably exactly twelve. A step of bringing the transistors into a discharge state for discharging the high-power component by way of the control voltages means that a majority of the transistors or all transistors of the converter circuit are brought into the discharge state. The transistors in the discharge state are then used to discharge the high-power component. In this way, the present converter circuit makes it possible, due to its high number of transistors, that said transistors are sufficient to realize the discharge without the need for additional components such as additional resistors. According to the disclosure, it is preferably provided that a large proportion, in particular at least 80%, preferably at least 90%, particularly preferably at least 95%, of the electrical energy dissipated during discharge of the high-power component is converted into heat by way of the transistors. Preferably, the entire electrical energy dissipated during discharge of the high-power component is converted into heat by way of the transistors.

The transistors can be metal-oxide semiconductor field-effect transistors, i.e., so-called MOSFETs, which have three terminals called gate, source and drain. By way of a voltage applied to the gate, which presently is realized by the control voltage of the gate driver, an electric current is controlled that flows through the source and drain, i.e., through the drain-source channel. The gate driver is configured to control the transistors of the converter circuit by way of separate control voltages, in particular individually. The number of control outputs of the gate driver preferably corresponds to the number of transistors, wherein each of the control outputs is connected to the gate of one of the transistors for transmitting the respective control voltage.

Preferably, the high-power component has at least one capacitor, wherein the at least one capacitor is discharged to discharge the high-power component. The capacitor is charged and discharged during normal or converter mode of the high-power component in a targeted manner. The use of the capacitor ensures fault-free operation of the high-power component. The at least one capacitor is in particular an intermediate circuit capacitor and/or an interference suppression capacitor, preferably of class X.

The high-power component can be a high-voltage DC/DC converter, which is used to connect a high-voltage on-board electrical system to a load. The load can be an electric air conditioning compressor or an electric heater. The high-power component can be a high-voltage AC/DC converter that is connected to the motor vehicle’s high-voltage on-board electrical system. The high-power component can connect the high-voltage on-board electrical system to an on-board charger, which is used to charge the motor vehicle’s electrical energy storage device. It is conceivable that the converter circuit of the high-power component is used to convert a DC voltage present on the part of a high-voltage on-board electrical system into an AC voltage present on the part of a load and/or vice versa. The high-power component preferably realizes a traction converter. In this case, the load is an electric machine that can be used to generate a traction torque for the vehicle. The DC voltage provided by the high-voltage on-board electrical system can be generated by way of the motor vehicle’s electrical energy storage device. The high-voltage electrical voltage of the high-voltage on-board electrical system can be in the range between 350 V and 860 V.

Preferably, the converter circuit is operated in a converter mode in which, for voltage conversion, the transistors, by way of the control voltages, are selectively brought into a conducting state, in which the drain-source channel of the respective transistor is in an electrically conducting state, or into a blocking state, in which the drain-source channel of the respective transistor is in an electrically blocking state. The converter mode realizes the original or intended purpose of the converter circuit, i.e., turning an existing DC voltage into an alternating voltage or rectifying an existing AC voltage. The control voltage applied to the gate can be present as a pulse-width modulated signal.

To discharge the high-power component, the converter circuit can be operated in a discharging mode in which the transistors are brought into the discharge state by way of the control voltages. The converter circuit is brought into the discharging mode if there is a circumstance that makes it necessary to discharge the high-power component. One such circumstance could be the occurrence of an accident. Thus, a control device can be provided, in particular on the part of the motor vehicle, which is configured to generate control signals and output them to the gate driver in the event of such a circumstance, causing the gate driver to generate the control voltages in such a way that the transistors are brought into the discharge state.

Specifically, it is conceivable that a voltage value of the control voltage that causes the conducting state is positive, while a voltage value of the control voltage that causes the blocking state is negative. The positive voltage value can be +15 V. The negative voltage value can be -4 V. A voltage value of the control voltage causing the discharge state can be positive and lower than the voltage value causing the conducting state. In this case, the transistor in the discharge state is operated in a linear or ohmic operating range. The corresponding voltage value can be selected from an interval that is limited at the bottom by a minimum voltage and at the top by a maximum voltage. The minimum voltage can be 0 V or a voltage value at which the resulting resistance of the drain-source channel assumes a certain value. The maximum voltage can correspond to the specified positive voltage value. The resulting resistance in the drain-source channel depends on this voltage value and can be specifically selected according to the current requirements, in particular separately and differently for each transistor. In other or general terms, it is conceivable that the or a voltage value of the control voltage causing the discharge state is selected from a voltage interval, in particular depending on the situation, wherein the value of the resistance realized by way of the respective drain-source channel depends on this voltage value. Typically, for positive voltage values, the value of the resistance present in the drain-source channel decreases as the control voltage increases.

Specifically, the voltage value of the control voltage causing the discharge state can be selected depending on a predetermined time period for discharging the high-power component. In situations where rapid discharge is required, the control voltages can be generated in such a way that the discharge takes place correspondingly quickly. Such situations arise, for example, if the discharge has to take place due to existing damage, which can occur in the event of an accident.

It is also conceivable that the transistors are thermally connected to at least one cooling component in such a way that heat is dissipated from the transistors by way of the at least one cooling component when the high-power component is discharged. Thus, during discharge, in which the electrical energy is dissipated by way of the transistors, heat is generated by the transistors, which is dissipated by way of the cooling component. The cooling component can be a device, such as a cooling plate, through which a coolant, particularly a liquid coolant, flows. The components of the converter circuit can be arranged on a circuit board or a printed circuit board, which in turn is thermally connected to the cooling component. The circuit board or printed circuit board and the cooling component can be in direct contact with one another. The cooling component can be integrated into a cooling circuit of the motor vehicle in which a coolant circulates. Other components such as heat exchangers, evaporators and/or the like can be integrated into the cooling circuit. The cooling circuit is preferably an active cooling system that forms a refrigeration machine.

The present disclosure also relates to a power electronics arrangement that comprises a high-power component with a plurality of transistors connected to form a multiphase T-type converter circuit and a gate driver, by way of which control voltages can be generated for the transistors, wherein it is possible to control an electrical current flow of a drain-source channel of the respective transistor by way of the control voltages, wherein the gate driver is configured to generate the control voltages in such a way that, for discharging the high-power component, the transistors of the converter circuit are brought, by way of the control voltages, into a discharge state in which the drain-source channel of the respective transistor realizes a resistance so that the high-power component can be discharged by way of these resistances. All the advantages, features and aspects discussed in connection with the method according to the disclosure are equally transferable to the power electronics arrangement according to the disclosure and vice versa.

Finally, the present disclosure also relates to a motor vehicle that comprises at least one power electronics arrangement according to the preceding description passage. All the advantages, features and aspects discussed in connection with the method according to the disclosure and the power electronics arrangement according to the disclosure are equally transferable to the motor vehicle according to the disclosure and vice versa.

### BRIEF DESCRIPTION OF THE SEVERAL VIEWS OF THE DRAWINGS

Further advantages, features, and details of the present disclosure are apparent from the exemplary embodiments discussed below and from the figures. The figures show schematically:

FIG. 1 is a schematic diagram of a motor vehicle according to the disclosure in accordance with an exemplary embodiment, comprising a power electronics arrangement according to the disclosure in accordance with an exemplary embodiment, wherein a method according to the disclosure in accordance with an exemplary embodiment is discussed with reference to this motor vehicle,

FIGS. 2 and 3 are characteristic curves of transistors of the power electronics arrangement of the motor vehicle of FIG. 1,

FIG. 4 is a circuit diagram of a high-power component of the power electronics arrangement of the motor vehicle of FIG. 1 realizing a converter circuit, wherein the converter circuit is in a converter mode, and

FIG. 5 is an equivalent circuit diagram of the converter circuit in discharging mode according to FIG. 4.

### DETAILED DESCRIPTION

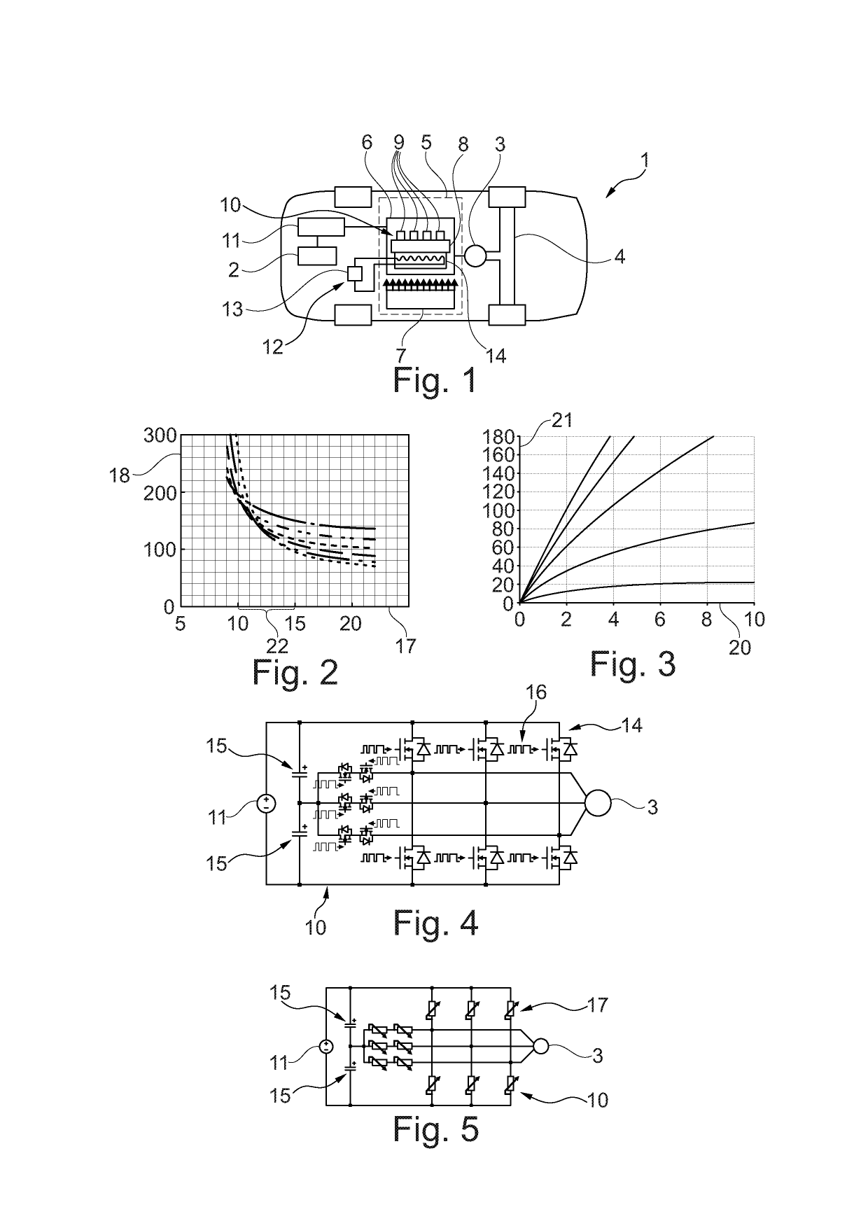

FIG. 1 shows a schematic diagram of a motor vehicle 1 according to the disclosure in accordance with an exemplary embodiment, by way of which a method according to the disclosure in accordance with an exemplary embodiment is discussed below. The motor vehicle 1 is designed as a hybrid or electric vehicle in which electrical energy stored in an electrical energy storage device 2 is converted into kinetic energy of the motor vehicle 1 by way of an electric machine 3 forming a traction motor, generating a drive torque, and vice versa in the context of a recuperation mode. The electric machine 3 is connected to the wheels of the motor vehicle 1 via a drive train 4.

Furthermore, the motor vehicle 1 comprises a power electronics arrangement 5 according to an exemplary embodiment, which in turn comprises a high-power component 6 and a gate driver 7. The high-power component 6 comprises a plurality of electronic components 9 arranged on a circuit board 8 and implements a converter circuit 10 realizing a traction converter. By way of the converter circuit 10, a direct current (DC) voltage present from a high-voltage on-board electrical system 11 is converted into an alternating current (AC) voltage present from the electric machine 3, which here forms a consumer. The high-voltage on-board electrical system 11 is supplied with voltage by the electrical energy storage device 2.

The circuit board 8 is connected to a cooling component 14, which in the present case is a cooling plate through which a liquid coolant circulating in an active cooling system 12 flows and thus serves to cool the electronic components 9. Further components 13 are integrated into the cooling system 12, including a heat exchanger, an evaporator and the like.

Details of the converter circuit 10 are discussed below. As already mentioned, said converter circuit comprises a plurality of electronic components 9, namely a plurality of transistors 14, specifically twelve in the present case, connected to form a three-phase T-type converter circuit, as well as capacitors 15, which realize an intermediate circuit capacitor and an interference suppression capacitor. FIGS. 2 and 3 each show characteristic curves of the transistors 14, wherein FIG. 4 shows a circuit diagram of the converter circuit 10. For the sake of clarity, only one of the transistors 14 is provided with the corresponding reference sign in FIG. 4. The gate driver 7 is provided to control the transistors 14, wherein, for this purpose, it generates corresponding control voltages 16 and outputs them to the gate terminals of the transistors 14. The control voltages 16 are present as pulse-width modulated signals in a normal or converter operation of the converter circuit 10, in which it carries out either the rectification or alternation of electrical voltage. The control voltages 16 are symbolically indicated by arrows in FIG. 1 and, for the sake of clarity, are only provided once with the corresponding reference sign in FIG. 4.

To realize the converter mode, the transistors 14 are selectively and cyclically brought into a conductive state and into a blocking state for voltage conversion by way of the control voltages 16. In relation to the conductive state, a drain-source channel of the respective transistor 14 is in an electrically conductive state. In relation to the blocking state, the drain-source channel of the respective transistor 14 is in an electrically blocking state. A voltage value of the control voltage 16 that causes the conducting state is positive and is +15 V, for example. A voltage value of the control voltage 16 that causes the blocking state is negative and is -4 V, for example.

The method according to the disclosure is directed to discharging the high-power component 6, specifically the capacitors 15. For this purpose, the converter circuit 10 is operated in a discharging mode or brought into such a mode, in which the transistors 14 are brought into a discharge state by way of the control voltages 16, in which the drain-source channel of the respective transistor 14 realizes an electrical resistance 17, wherein the capacitors 15 are discharged by way of the resistances 17. Specifically, the electrical energy stored in the capacitors 15 is dissipated or converted into heat, which is dissipated by the cooling component 14.

The converter circuit 10 is switched to discharging mode when a circumstance arises that makes it necessary to discharge the high-power component 6. For this purpose, the motor vehicle 1 is provided with a control device, not shown in the figures, which generates control signals and outputs them to the gate driver 7 when such a circumstance arises, for example when sensors detect the occurrence or imminent occurrence of an accident, causing the gate driver 7 to generate the control voltages in such a way that the transistors 14 are brought into the discharge state.

The transistors 14 in the discharge state are in an ohmic or linear operating mode, in which the respective transistor 14 behaves at least approximately like an ohmic resistance. Here, reference is made to the characteristic curves of the transistors 14 shown in FIGS. 2 and 3. In the coordinate system shown in FIG. 2, the abscissa 18 refers to a gate-source voltage, which corresponds to the value of the control voltage 16 in volts, and the ordinate 19 refers to the resulting resistance 17 of the drain-source channel of the respective transistor 14 in mΩ. The six characteristic curves shown in FIG. 2 apply to different temperature values, wherein, with reference to the right-hand part of this figure, the top characteristic curve applies to a temperature of 150 °C and the bottom characteristic curve applies to a temperature of 25 °C, wherein the intermediate characteristic curves relate to the intermediate temperatures in 25 °C increments. In the coordinate system shown in FIG. 3, the abscissa 20 refers to an applied drain-source voltage in volts and the ordinate 21 to a resulting drain-source current in amperes. The five characteristic curves shown in FIG. 3 show the approximate linear behavior as with an ohmic resistance, wherein the top characteristic curve applies to a gate-source voltage of 15 V and the bottom characteristic curve to a gate-source voltage of 7 V, wherein the intermediate characteristic curves relate to the intermediate values for the gate-source voltage in 2 V increments.

The value of the control voltage 16 causing the discharge state of the transistors 14 is selected from a voltage interval 22 indicated in FIG. 2. The voltage interval 22 relates precisely to those values for the gate-source voltage at which the respective transistor 14 is operated in the ohmic or linear operating mode. The voltage interval 22 is limited at the bottom by a minimum voltage and at the top by a maximum voltage. The minimum voltage can be 0 V, but in the present case it is a voltage value at which the resulting resistance of the drain-source channel assumes a certain value. For example, the minimum voltage is 10 V. The maximum voltage corresponds to the positive voltage value, i.e., 15 V. It is apparent that the resulting resistance 17 of the drain-source channel depends on this voltage value.

FIG. 5 shows an equivalent circuit diagram of the circuit diagram shown in FIG. 4, in which the transistors 14 each realize the resistance 17. For the sake of clarity, only one of these resistances 17 is provided with the corresponding reference sign. In the present case, the transistors 14 are brought into the discharge state in such a way that they all have the same value for the electrical resistance. However, it is also conceivable that different values are generated in this respect.

The actual selection of the resistance value is situation-specific. Thus, it is provided that the voltage value of the control voltage 16 causing the discharge state is selected depending on a predetermined time duration for discharging the high-power component 6. Therefore, in situations where rapid discharge is required, the control voltages 16 are generated in such a way that the discharge takes place correspondingly quickly. Such a situation arises, for example, if an accident involving the motor vehicle 1 is currently occurring or imminent and there is a risk of mechanical damage of the high-power component 6.

German patent application no. 102025103098.7, filed Jan.29, 2025, to which this application claims priority, is hereby incorporated herein by reference, in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A method of discharging a power component of a motor vehicle, wherein the power component includes a plurality of transistors connected to form a multiphase T-type converter circuit, the method comprising:
generating, by a gate driver, a plurality of control voltages for the plurality of transistors,
wherein an electrical current flow of a drain-source channel of each of the plurality of transistors is controlled by the control voltages,
wherein, for discharging the power component, each of the plurality of transistors of the multiphase T-type converter circuit is brought into a discharge state by way of the control voltages,
wherein the drain-source channel of each of the plurality of transistors realizes a resistance, and
wherein the discharging of the power component takes place by way of the resistance realized by the drain-source channel of each of the plurality of transistors.

2. The method according to claim 1, wherein
the power component includes at least one capacitor, and
the discharging of the power component includes discharging the at least one capacitor.

3. The method according to claim 2, wherein the at least one capacitor includes an intermediate circuit capacitor and/or an interference suppression capacitor.

4. The method according to claim 1, further comprising:
converting, by the multiphase T-type converter circuit of the power component, a direct current (DC) voltage present on an on-board electrical system of the motor vehicle into an alternating current (AC) voltage present on a load; and/or
converting, by the multiphase T-type converter circuit of the power component, the AC voltage present on the load into the DC voltage present on the on-board electrical system of the motor vehicle.

5. The method according to claim 4, wherein the multiphase T-type converter circuit is a traction converter.

6. The method according to claim 3, further comprising:
operating the multiphase T-type converter circuit in a converter mode in which, for voltage conversion, the transistors are selectively brought, by way of the control voltages, into a conducting state, in which the drain-source channel of each of the transistors is in an electrically conducting state, or into a blocking state, in which the drain-source channel of each of the transistors is in an electrically blocking state, and
operating the multiphase T-type converter circuit in a discharging mode in which the power component is discharged and each of the transistors is brought into the discharge state by way of the control voltages.

7. The method according to claim 6, wherein
a voltage value of the control voltages causing the conducting state is positive,
a voltage value of the control voltages causing the blocking state is negative, and
a voltage value of the control voltages causing the discharge state is positive and smaller than the voltage value causing the conducting state.

8. The method according to claim 1, wherein
a voltage value of the control voltages causing the discharge state is selected from a voltage interval, and
a value of the resistance realized by the drain-source channel of each of the plurality of transistors depends on the voltage value.

9. The method according to claim 8, wherein
the voltage value of the control voltages causing the discharge state is selected based on a predetermined time duration for discharging the power component.

10. The method according to claim 1, wherein
the transistors are thermally connected to at least one cooling component in such a way that heat is dissipated from the transistors by way of the at least one cooling component when the power component is discharged.

11. A power electronics arrangement, comprising:
a power component that includes a plurality of transistors connected to form a multiphase T-type converter circuit; and
a gate driver that, in operation, generates control voltages for the transistors,
wherein an electrical current flow of a drain-source channel of each the transistors is controlled by way of the control voltages,
wherein the gate driver generates the control voltages in such a way that, for discharging the power component, the transistors of the multiphase T-type converter circuit are brought, by way of the control voltages, into a discharge state in which the drain-source channel of each of the transistors realizes a resistance, and
wherein the power component is discharged by way of the resistance realized by the drain-source channel of each of the plurality of transistors.

12. A motor vehicle, comprising the power electronics arrangement according to claim 11.
